(19) United States
(12) Patent Application Publication
(10) Pub. No.: US 2024/0312809 A1
(43) Pub. Date: Sep. 19, 2024

(54) SEMICONDUCTOR MANUFACTURING APPARATUS

(71) Applicant: Kioxia Corporation, Tokyo (JP)

(72) Inventor: Takashi OHASHI, Yokkaichi Mie (JP)

(73) Assignee: Kioxia Corporation, Tokyo (JP)

(21) Appl. No.: 18/590,235

(22) Filed: Feb. 28, 2024

(30) Foreign Application Priority Data
Mar. 16, 2023 (JP) 2023-041757

(51) Int. Cl. H01L 21/67; H01L 21/677

(52) U.S. Cl. CPC H01L 21/67167; H01L 21/67173; H01L 21/6773

(57) ABSTRACT

A semiconductor manufacturing apparatus includes a front end module with a load port to which a conveyance container is connected on an upper surface; and a plurality of processing units configured to process a semiconductor substrate, disposed around the front end module in a plan view from a normal direction of the upper surface of the front end module, and each connected to the front end module from at least two directions in the plan view. The semiconductor substrate is conveyed between the conveyance container and the processing units via the front end module.

### CROSS-REFERENCE TO RELATED APPLICATION

This application is based upon and claims the benefit of priority from Japanese Patent Application No. 2023-041757, filed Mar. 16, 2023, the entire contents of which are incorporated herein by reference.

### FIELD

Embodiments described herein relate generally to a semiconductor manufacturing apparatus.

### BACKGROUND

In the manufacturing process of the semiconductor device, a semiconductor substrate to be processed is stored in a conveyance container and conveyed. In a semiconductor manufacturing apparatus used in a manufacturing process of a semiconductor device, a front end module (equipment front end module; EFEM) is used for conveying a semiconductor substrate between a conveyance container and a processing chamber in which the semiconductor substrate is processed. By increasing the number of processing chambers connected to the front end module, the number of semiconductor substrates to be processed simultaneously can be increased.

### DESCRIPTION OF THE DRAWINGS

FIG. 1 is a schematic plan view showing a configuration of a semiconductor manufacturing apparatus according to the embodiment.

FIG. 2 is a schematic side view showing a configuration of the semiconductor manufacturing apparatus according to the embodiment.

FIG. 3 is a schematic view showing an example of movement of the conveyance container in the semiconductor manufacturing apparatus according to the embodiment.

FIG. 4 is a schematic view showing an example of the conveyance of the semiconductor substrate in the semiconductor manufacturing apparatus according to the embodiment.

FIG. 5 is a schematic view showing an example of a robot arm.

FIG. 6 is a schematic view showing a configuration of a semiconductor manufacturing apparatus of a comparative example.

FIG. 7 is a schematic plan view showing a configuration of a base unit of the semiconductor manufacturing apparatus according to the embodiment.

FIG. 8 is a schematic view showing an example of the conveyance of the semiconductor substrate in the base unit.

FIG. 9 is a schematic plan view showing another configuration of the base unit of the semiconductor manufacturing apparatus according to the embodiment.

FIG. 10 is a schematic plan view showing an example of the arrangement of the unit group of the semiconductor manufacturing apparatus according to the embodiment.

FIG. 11 is a schematic view of the semiconductor manufacturing apparatus showing the control method of the semiconductor manufacturing apparatus according to the embodiment.

FIG. 12 is a flowchart showing a control method of the semiconductor manufacturing apparatus according to the embodiment.

### DETAILED DESCRIPTION

Embodiments provide a semiconductor manufacturing apparatus capable of increasing the number of processing chambers connected to a front end module.

In general, according to one embodiment, there is provided a semiconductor manufacturing apparatus including a front end module with a load port to which a conveyance container is connected on an upper surface; and a plurality of processing units configured to process a semiconductor substrate, disposed around the front end module in a plan view from a normal direction of the upper surface of the front end module, and each connected to the front end module from at least two directions in the plan view. The semiconductor substrate is conveyed between the conveyance container and the processing units via the front end module.

Next, embodiments will be described with reference to drawings. In the description of the drawings to be described below, the same or similar parts are denoted by the same or similar reference numerals. The drawings are schematic. Further, the embodiments shown below are examples of devices and methods for embodying the technical idea, and the materials, shapes, structures, arrangements, and the like of the components are not specified. Embodiments may be modified in various ways.

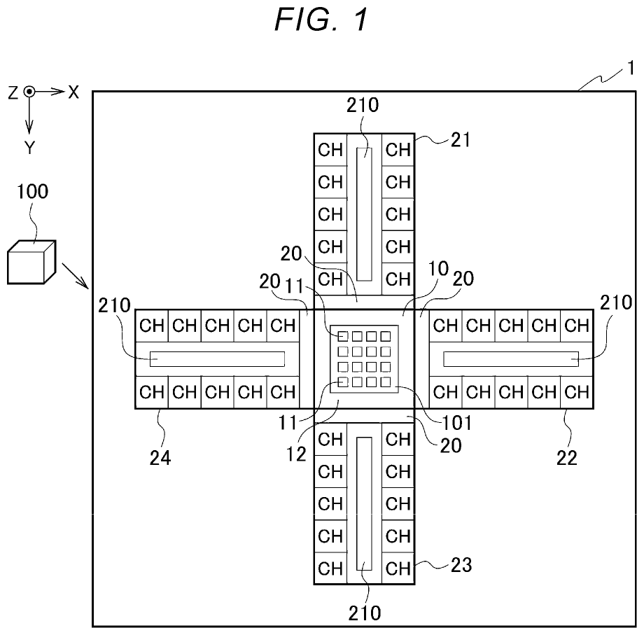

A semiconductor manufacturing apparatus 1 according to the embodiment shown in FIG. 1 processes a semiconductor substrate conveyed by a conveyance container 100. The semiconductor manufacturing apparatus 1 includes a front end module 10 with a load port 11 to which the conveyance container 100 is connected on an upper surface 101, and a first processing unit 21, a second processing unit 22, a third processing unit 23, and a fourth processing unit 24, which process the semiconductor substrate. As shown in FIG. 1, a plurality of load ports 11 are disposed on the upper surface 101 of the front end module 10. FIG. 1 shows a case where the number of load ports 11 is sixteen as an example.

Hereinafter, when each of the first processing unit 21 to the fourth processing unit 24 is not limited, the first processing unit 21 to the fourth processing unit 24 are referred to as the processing unit 20. The processing unit 20 includes a plurality of processing chambers CH in each of which the semiconductor substrate is processed and a conveyance device 210 that conveys the semiconductor substrate in the processing unit 20. The processing units shown in FIG. 1 each have ten processing chambers CH. As shown in FIG. 1, five processing chambers CH are arranged in two rows with the conveyance device 210 interposed therebetween.

The processing unit 20 is disposed around the front end module 10 when viewed from the normal direction of the upper surface 101 of the front end module 10 (hereinafter, also referred to as “plan view”). Each of the processing units 20 is connected to the front end module 10 from different directions.

As shown in FIG. 1, the normal direction of the upper surface 101 of the front end module 10 is denoted by a Z direction. In FIG. 1, a Z direction is a depth direction of a paper, an X direction is a right-left direction of the paper, and a Y direction is an up-down direction of the paper. In other words, the upper surface 101 is parallel to an XY plane perpendicular to the Z direction.

In the semiconductor manufacturing apparatus 1 shown in FIG. 1, the processing unit 20 is connected to the front end module 10 from four directions orthogonal to each other in a plan view. In other words, the processing units 20 are disposed on the upper, lower, left, and right sides of the front end module 10 in a plan view with the front end module 10 as a center, respectively. In the paper of FIG. 1, the first processing unit 21 is connected from the upper side of the front end module 10 having a rectangular shape in a plan view. The second processing unit 22 is connected from the right side of the front end module 10. The third processing unit 23 is connected from the lower side of the front end module 10. The fourth processing unit 24 is connected from the left side of the front end module 10. In other words, the first processing unit 21 and the third processing unit 23 extend in the Y direction. The second processing unit 22 and the fourth processing unit 24 extend in the X direction.

As shown in FIG. 1, the processing unit 20 is connected to the front end module 10 from directions orthogonal to each other, so that an extension length of each processing unit 20 can be set freely. Therefore, the number of processing chambers CH provided in the processing unit 20 can be easily increased.

The number of processing units 20 of the semiconductor manufacturing apparatus 1 is not limited to four, but the semiconductor manufacturing apparatus 1 includes the plurality of processing units 20. In other words, the processing unit 20 is connected to the front end module 10 from at least two directions in a plan view.

The semiconductor manufacturing apparatus 1 conveys the semiconductor substrate between the conveyance container 100 and the processing unit 20 via the front end module 10. Hereinafter, an operation of the semiconductor manufacturing apparatus 1 will be described.

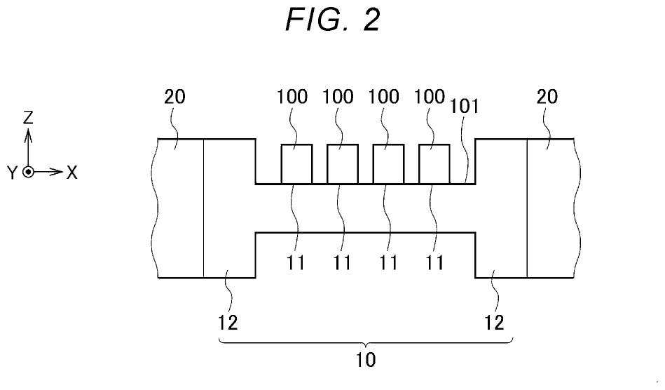

As shown in FIG. 2, the conveyance container 100 in which the semiconductor substrate to be processed is stored is connected to the load port 11. Although not shown, the load port 11 has a mechanism for fixing the conveyance container 100 to a predetermined position, a mechanism for opening and closing the door of the conveyance container 100 to allow an inside of the conveyance container 100 and an inside of the front end module 10 to communicate with each other, a mechanism for transferring the semiconductor substrate, and the like. As the conveyance container 100, for example, a front opening unified pod (FOUP) whose inside is sealed in order to maintain the cleanliness around the semiconductor substrate may be used. The front end module 10 includes a connection device 12 that transfers the semiconductor substrate between the front end module 10 and the processing unit 20. Each of the connection devices 12 is disposed in regions connected to the processing unit 20 of the front end module 10.

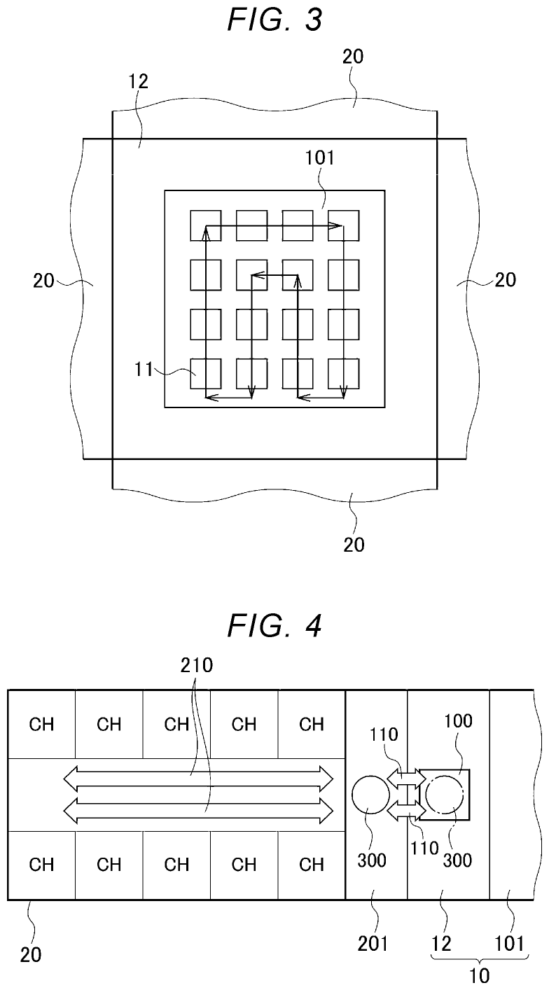

The front end module 10 moves the conveyance container 100 on the upper surface 101 so that the conveyance container 100 is close to the connection device 12 to which the processing unit 20 that processes the semiconductor substrate stored in the conveyance container 100 is connected. For example, the conveyance container 100 moves on the upper surface 101 in a certain route as indicated by an arrow in FIG. 3. In FIG. 3, an example in which the conveyance container 100 moves in a zigzag manner is shown, but a method of moving the conveyance container 100 may be set freely. By sequentially moving the conveyance container 100 around the plurality of load ports 11 set on the upper surface 101, the semiconductor substrate can be smoothly moved to any front end module 10.

The semiconductor substrate is conveyed to the processing unit 20 from the conveyance container 100 conveyed to the connection device 12 of the front end module 10. Thereafter, the semiconductor substrate is processed in a predetermined processing chamber CH of the processing unit 20. For example, a photolithography process or a film forming process is performed in the processing chamber CH. The semiconductor substrate processed in the processing chamber CH is returned from the connection device 12 to the conveyance container 100 disposed in the processing unit 20.

The semiconductor substrate may be conveyed between the front end module 10 and the processing unit 20 by, for example, the transfer mechanism 110 and the conveyance device 210 as shown in FIG. 4. In the example of the conveying method shown in FIG. 4, the semiconductor substrate 300 is taken out from the conveyance container 100 conveyed to the connection device 12, by the transfer mechanism 110 of the front end module 10, and is transferred to the substrate arrangement region 201 of the processing unit 20. The processing unit 20 conveys the semiconductor substrate 300 from the substrate arrangement region 201 to an inside of the predetermined processing chamber CH by using the conveyance device 210. The semiconductor substrate 300 processed in the processing chamber CH is conveyed to the conveyance container 100 by the conveyance device 210 and the transfer mechanism 110.

In the example shown in FIG. 4, two transfer mechanisms 110 and two conveyance devices 210 are disposed along an array direction of the processing chamber CH. For example, the semiconductor substrate may be conveyed to the processing chamber CH of one row of the processing chambers CH arranged in two rows in the processing unit 20 by one set of the transfer mechanism 110 and the conveyance device 210.

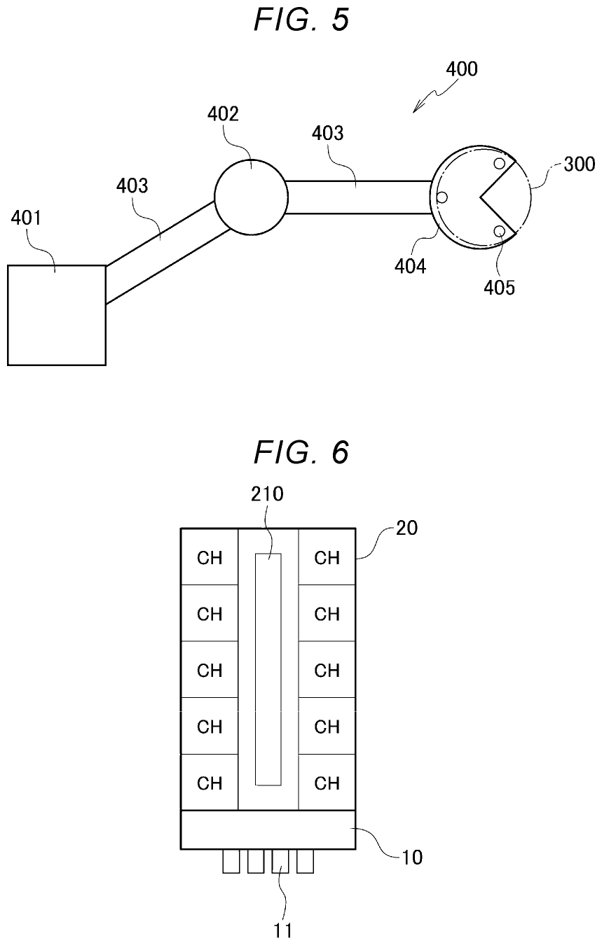

The conveyance device 210 may be, for example, a robot arm. FIG. 5 shows an example of a robot arm 400 that can be used for the conveyance device 210 and the transfer mechanism 110. The robot arm 400 includes a fixing unit 401, an arm 403 connected to the fixing unit 401 and freely bent at a joint 402, and a mounting portion 404 connected to an end portion of the arm 403 and mounting the semiconductor substrate 300. The semiconductor substrate 300 is supported by, for example, the support portion 405 disposed on the surface of the mounting portion 404.

FIG. 6 shows a configuration of a semiconductor manufacturing apparatus of the comparative example. In the semiconductor manufacturing apparatus of the comparative example, the processing unit 20 is connected to one side surface of the front end module 10, and the load port 11 is disposed on the other side surface. In the semiconductor manufacturing apparatus of the comparative example, the number of load ports 11 is limited depending on the length of the side surface of the front end module 10. Therefore, when the number of processing chambers CH of the processing unit 20 is increased, the number of load ports 11 is not sufficient with respect to the number of processing chambers CH. Meanwhile, when the number of processing chambers CH is increased to correspond to the number of load ports 11, an installation area of the front end module 10 is increased.

In contrast, in the semiconductor manufacturing apparatus 1 shown in FIG. 1, a large number of load ports 11 are disposed on the upper surface 101 of the front end module 10. Therefore, according to the semiconductor manufacturing apparatus 1, even if the number of processing chambers CH of the processing unit 20 is increased, it is possible to prevent the number of load ports 11 from being insufficient with respect to the number of processing units 20.

A type of the processing chamber CH provided in the processing unit 20 may be selected freely. For example, as the number of processing chambers CH for performing the same process increases, the number of semiconductor substrates processed at the same time can be increased. As a result, a process efficiency in the semiconductor manufacturing apparatus 1 is improved. Alternatively, a series of manufacturing processes may be executed by one processing unit 20 configured with a plurality of processing chambers CH for performing different processes.

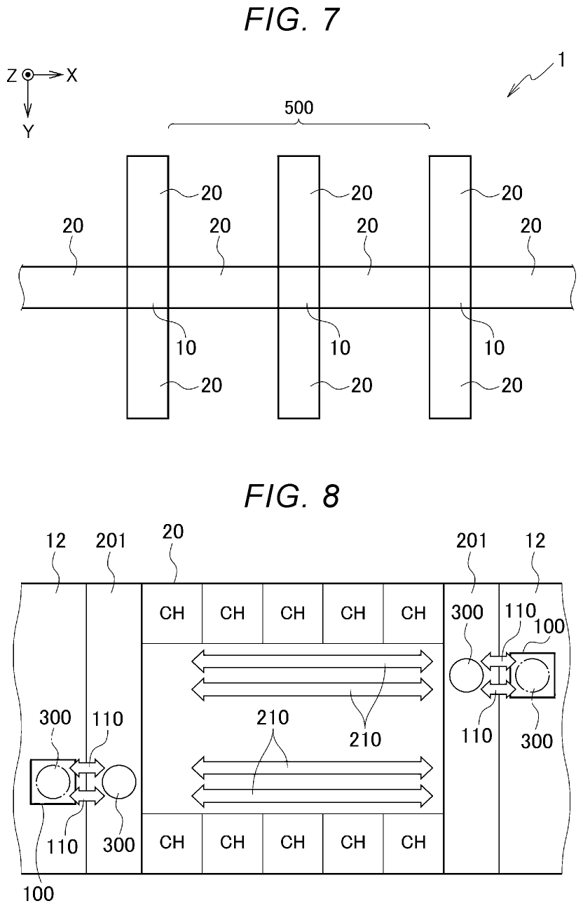

In addition, as shown in FIG. 7, a configuration in which a plurality of processing units 20 are connected to the front end module 10 may be regarded as the base unit 500, and the semiconductor manufacturing apparatus 1 may be configured with the plurality of base units 500 that are connected to each other while sharing one of the processing units 20. In the semiconductor manufacturing apparatus 1 shown in FIG. 7, two front end modules 10 are connected to the processing unit 20 extending in the Y direction.

For example, in the semiconductor manufacturing apparatus of the comparative example shown in FIG. 6, there is one front end module 10 connected to one processing unit 20. Therefore, when the semiconductor substrate cannot be conveyed between the front end module 10 and the processing unit 20 due to a failure or maintenance of the front end module 10, the semiconductor substrate cannot be processed in all the processing chambers CH of the processing unit 20.

In contrast, in the semiconductor manufacturing apparatus 1 shown in FIG. 7, in the processing unit 20 to which the two front end modules 10 are connected, when one front end module 10 cannot be used, the other front end module 10 can be used. Therefore, the semiconductor substrate can be processed in all the processing chambers CH provided in the processing unit 20.

The processing unit 20 to which two front end modules 10 are connected may include, for example, two conveyance sets each including two transfer mechanisms 110 and two conveyance devices 210, as shown in FIG. 8. One conveyance set conveys the semiconductor substrate 300 between the processing unit 20 and one front end module 10. Another conveyance set conveys the semiconductor substrate 300 between the processing unit 20 and the other front end module 10.

In the processing unit 20 in which the two front end modules 10 are connected, the semiconductor substrate can be conveyed from the front end module 10 on the side closer to the processing chamber CH. Therefore, a distance to convey the semiconductor substrate becomes shorter. As a result, the conveyance time can be shortened, and the occurrence of the positional deviation of the semiconductor substrate in the conveyance device 210 during the conveyance can be reduced.

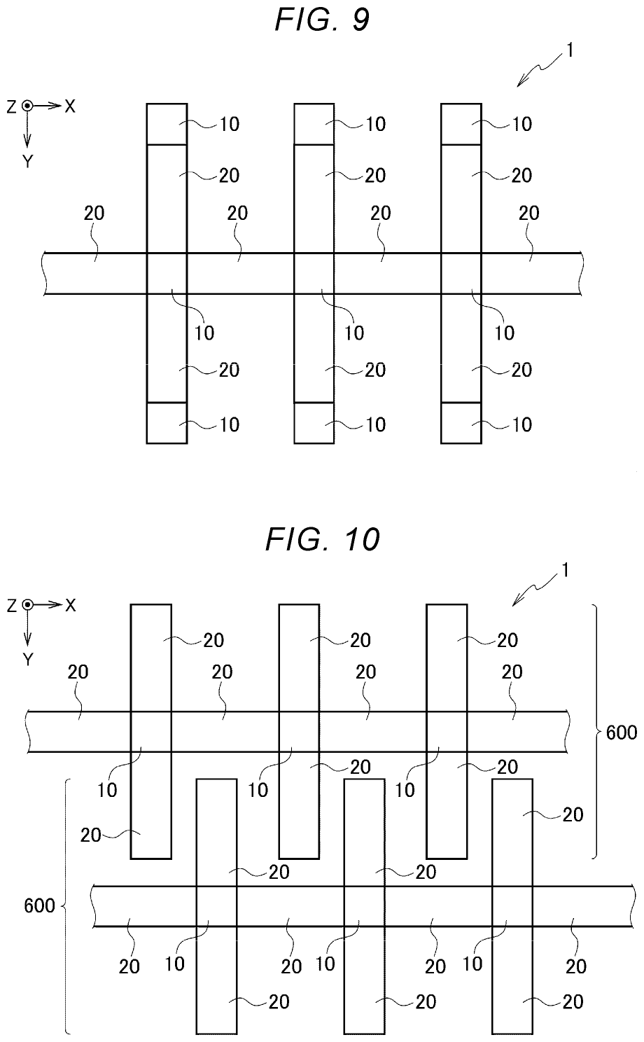

As shown in FIG. 9, the base unit of the semiconductor manufacturing apparatus 1 may include a front end module 10 connected only to the processing unit 20 not shared with other base units. According to the semiconductor manufacturing apparatus 1 shown in FIG. 9, all the processing units 20 of the semiconductor manufacturing apparatus 1 are connected to two front end modules 10. Accordingly, in any of the processing units 20, the semiconductor substrate can be conveyed by the other front end module 10 to be connected even when one front end module 10 to be connected cannot be used.

As shown in FIG. 10, when the semiconductor manufacturing apparatus 1 includes a plurality of unit groups 600 in which a plurality of base units are connected, the unit groups 600 may be disposed such that the processing units 20 of the adjacent unit groups 600 are alternately arranged. By placing the unit group 600 close to each other so that the processing units 20 are disposed in a staggered manner, the installation area of the semiconductor manufacturing apparatus 1 can be reduced.

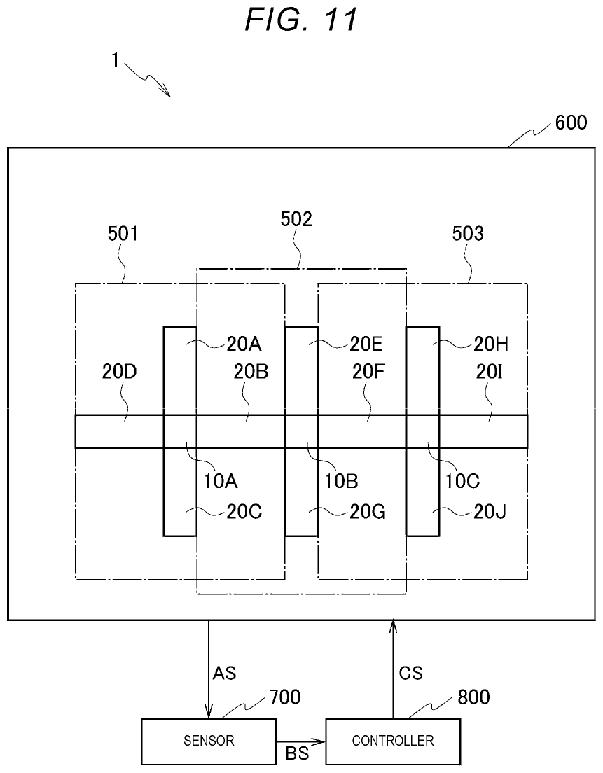

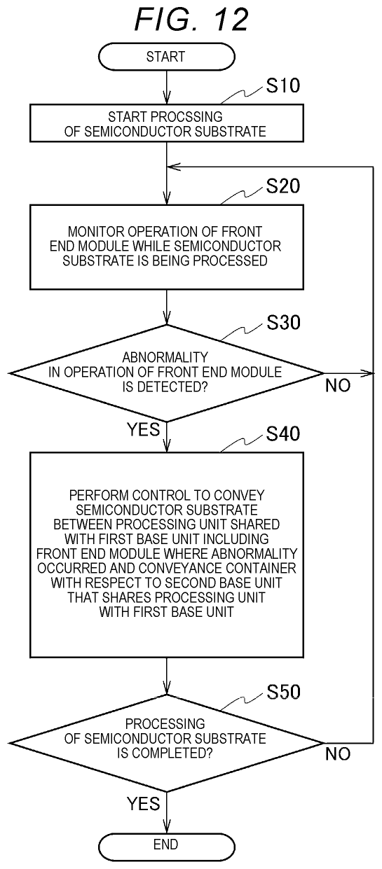

As described above, according to the semiconductor manufacturing apparatus 1 configured with the plurality of base units 500, the process of the semiconductor substrate can be continued even when one of the front end modules 10 does not operate. Hereinafter, by using the semiconductor manufacturing apparatus 1 shown in FIG. 11 as an example, an example of a control method of the semiconductor manufacturing apparatus 1 configured with the plurality of base units 500 will be described with reference to FIG. 12.

The semiconductor manufacturing apparatus 1 shown in FIG. 11 includes a unit group 600, a sensor 700, and a controller 800. The unit group 600 includes a first base unit 501, a second base unit 502, and a third base unit 503. The first base unit 501 includes a front end module 10A, and processing units 20A, 20B, 20C, and 20D connected to the front end module 10A. The second base unit 502 includes a front end module 10B, and processing units 20E, 20F, 20G, and 20B connected to the front end module 10B. The first base unit 501 and the second base unit 502 are connected to each other while sharing the processing unit 20B. The third base unit 503 includes the front end module 10C, and the processing units 20H, 20I, 20J, and 20F connected to the front end module 10C. The second base unit 502 and the third base unit 503 are connected to each other while sharing the processing unit 20F.

The sensor 700 monitors the operation of the front end module 10 provided in the unit group 600. The controller 800 controls the operation of the unit group 600.

First, in Step S10 of FIG. 12, the processing of the semiconductor substrate by the semiconductor manufacturing apparatus 1 shown in FIG. 11 is started. In step S20, the sensor 700 monitors the operation of the front end module 10 provided in the unit group 600 while the semiconductor substrate 300 is being processed. For example, as illustrated in FIG. 11, the unit group 600 notifies the sensor 700 of information on the operation of the front end module 10 by the operation information signal AS.

In step S30, when the sensor 700 does not detect the abnormality in the operation of the front end module 10, the process returns to step S20. On the other hand, when the sensor 700 detects an abnormality in the operation of the front end module 10, the sensor 700 notifies the controller 800 of information on the front end module 10 where the abnormality in the operation is detected (hereinafter, referred to as an “abnormal front end module”) by the abnormality detection signal BS. Thereafter, the process proceeds to step S40.

In Step S40, the controller 800 transmits the control signal CS to the unit group 600, and causes other front end modules 10 to convey the semiconductor substrate of the processing unit 20 connected to the abnormal front end module. Accordingly, the semiconductor substrate is conveyed between the processing unit 20 and the conveyance container 100 connected to the abnormal front end module. Therefore, the process of the semiconductor substrate can be continued even while the abnormal front end module is not operating.

For example, in the semiconductor manufacturing apparatus 1 shown in FIG. 11, it is assumed that the front end module 10 of the first base unit 501 failed. In this case, the controller 800 controls the unit group 600 to convey the semiconductor substrate between the processing unit 20B and the conveyance container 100 with respect to the second base unit 502 that shares the processing unit 20B with the first base unit 501. Accordingly, the semiconductor substrate is conveyed between the processing unit 20B and the conveyance container 100 by the front end module 10 of the second base unit 502. Therefore, the process in the processing unit 20B can be continued.

Thereafter, in step S50, it is determined whether the process of the semiconductor substrate is completed. When the process of the semiconductor substrate is not completed, the process returns to Step S20. When the process of the semiconductor substrate is completed, the process in the semiconductor manufacturing apparatus 1 is ended.

As described above, since the two front end modules 10 are connected to the processing unit 20, the semiconductor substrate can be conveyed by the other front end module 10 even if one front end module 10 fails. That is, when the sensor 700 detects an abnormality in the operation of one front end module 10 connected to the processing unit 20, the controller 800 controls the unit group 600 to perform the process of the semiconductor substrate using the other front end module 10. Therefore, the efficiency of the process of the semiconductor substrate by the semiconductor manufacturing apparatus 1 can be increased.

In addition, according to the semiconductor manufacturing apparatus 1 in which all of the processing units 20 described with reference to FIG. 9 are connected to the two front end modules 10, the process in all of the processing units 20 can be continued even when any of the front end modules 10 fails.

As described above, in the semiconductor manufacturing apparatus 1 according to the embodiment, the load port 11 is disposed on the upper surface 101 of the front end module 10, and the plurality of processing units 20 are disposed around the front end module 10 in a plan view. Therefore, according to the semiconductor manufacturing apparatus 1, even if the number of processing chambers CH of the processing unit 20 is increased, it is possible to prevent the number of load ports 11 from being insufficient with respect to the number of processing chambers CH. Therefore, the number of processing chambers CH of the processing unit 20 can be increased. Furthermore, according to the semiconductor manufacturing apparatus 1 configured with the plurality of base units 500, it is possible to reduce a decrease in process efficiency when the front end module 10 fails.

### Other Embodiments

In the above description, a case where the number of processing units 20 connected to one front end module 10 is four is described as an example, but the number of processing units 20 connected to the front end module 10 is not limited to four. For example, the number of processing units 20 connected to the front end module 10 may be two or three. In addition, in the above description, a case where the shape of the front end module 10 in the plan view is a rectangular shape is described, but the shape of the front end module 10 in the plan view may be a polygonal shape other than the rectangular shape. For example, the shape of the front end module 10 in a plan view may be a hexagonal shape, with the processing unit 20 connected to each side of the hexagonal shape. In other words, six processing units 20 may be connected to one front end module 10 to configure the base unit 500.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor manufacturing apparatus, comprising:
a front end module with a load port to which a conveyance container is connected; and
a plurality of processing units configured to process a semiconductor substrate, disposed around the front end module in a plan view from a normal direction of the upper surface of the front end module, and each connected to the front end module from at least two directions in the plan view,
wherein the semiconductor substrate is conveyed between the conveyance container and the processing units via the front end module.

2. The semiconductor manufacturing apparatus according to claim 1,
wherein the processing units include a plurality of processing chambers each configured to process semiconductor substrate.

3. The semiconductor manufacturing apparatus according to claim 1,
wherein the processing units are connected to the front end module from four directions orthogonal to each other in the plan view.

4. The semiconductor manufacturing apparatus according to claim 1, further comprising:
a plurality of base units connected to each other while sharing one of the processing units, wherein the plurality of processing units are connected to the front end module as a base unit.

5. A control method for the semiconductor manufacturing apparatus according to claim 4, the method comprising:
monitoring an operation of the front end module; and
when an abnormality while operating the front end module is detected, conveying the semiconductor substrate between the processing unit shared with a first base unit including the front end module where the abnormality has occurred and the conveyance container with respect to a second base unit that shares the processing unit with the first base unit.

6. The semiconductor manufacturing apparatus according to claim 1, wherein the conveyance container includes a front opening unified pod.

7. The semiconductor manufacturing apparatus according to claim 1, wherein the conveyance container is configured to transfer the substrate.

8. A semiconductor manufacturing apparatus, comprising:
a front end module with a load port to which a conveyance container is connected; and
a plurality of processing units configured to process a semiconductor substrate, disposed around the front end module in a plan view from a normal direction of the upper surface of the front end module, and each connected to the front end module from at least two directions in the plan view,
wherein the semiconductor substrate is conveyed between the conveyance container and the processing units via the front end module;
wherein the processing units are connected to the front end module from four directions orthogonal to each other in the plan view.
